(19) United States
(12) Patent Application Publication
(10) Pub. No.: US 2011/0256724 A1
(43) Pub. Date: Oct. 20, 2011

(54) GAS AND LIQUID INJECTION METHODS AND APPARATUS

(75) Inventors: Ramesh Chandrasekharan, Portland, OR (US); Antonio Xavier, West Linn, OR (US); Kevin Jennings, Lake Oswego, OR (US); Ming Li, West Linn, OR (US); Henri Jon, West Linn, OR (US); Dennis Hausmann, Lake Oswego, OR (US)

(73) Assignee: Novellus Systems, Inc., San Jose, CA (US)

(21) Appl. No.: 13/083,827

(22) Filed: Apr. 11, 2011

Related U.S. Application Data
(60) Provisional application No. 61/324,710, filed on Apr. 15, 2010.
(60) Provisional application No. 61/372,367, filed on Aug. 10, 2010.
(60) Provisional application No. 61/379,081, filed on Sep. 1, 2010.
(60) Provisional application No. 61/417,807, filed on Nov. 29, 2010.
(60) Provisional application No. 61/439,619, filed on Feb. 4, 2011.

(51) Int. Cl. H01L 21/311; B67D 7/06; B67D 7/14

(52) U.S. Cl. 438/694; 222/54; 222/1; 257/E21.214

(57) ABSTRACT

A liquid injection system for a processing chamber includes a liquid injector that receives a liquid from a liquid supply and that selectively pulses the liquid into a conduit. A control module selects a number of pulses and a pulse width of the liquid injector. A gas supply supplies gas into the conduit. A sensor senses at least one of a first temperature and a first pressure in the conduit and that generates at least one of a first temperature signal and a first pressure signal, respectively. The control module confirms that the selected number of pulses occur based on the at least one of the first temperature signal and the first pressure signal.

### CROSS-REFERENCE TO RELATED APPLICATIONS

This application claims the benefit of U.S. Provisional Application No. 61/324,710, filed on Apr. 15, 2010, U.S. Provisional Application No. 61/372,367, filed on Aug. 10, 2010, U.S. Provisional Application No. 61/379,081, filed on Sep. 1, 2010, U.S. Provisional Application No. 61/417,807, filed on Nov. 29, 2010 and U.S. Provisional Application No. 61/439,619, filed on Feb. 4, 2011. The disclosures of the above applications are incorporated herein by reference in their entirety.

### FIELD

The present disclosure relates to gas and liquid injection systems and methods, and more particularly to gas and liquid injection systems and methods for film deposition and other processes.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

During semiconductor processing, films may need to be deposited on a substrate. A semiconductor processing system deposits the film in a processing chamber. A substrate may be positioned on a pedestal that is located in the processing chamber. To deposit the film, a precursor gas may be supplied to the processing chamber for a predetermined period. After exposing the substrate, the precursor gas may be purged from the processing chamber. Then, oxidation or plasma treatment may be performed. These steps may be repeated a number of times to build up the thickness of the film on the substrate.

Mass flow controllers may be used to meter the flow of a precursor liquid that is vaporized into the precursor gas that is supplied to the processing chamber. For some films, once saturation of the precursor gas is reached in the processing chamber, any additional precursor gas that is added is wasted. Therefore very precise metering of the precursor liquid and/or gas is required to minimize production costs. However, precise mass flow controllers are also very expensive, which increases the cost of the semiconductor processing equipment.

### SUMMARY

A liquid injection system for a processing chamber includes a liquid injector that receives a liquid from a liquid supply and that selectively pulses the liquid into a conduit. A control module selects a number of pulses and a pulse width of the liquid injector. A gas supply supplies gas into the conduit. A sensor senses at least one of a first temperature and a first pressure in the conduit and generates at least one of a first temperature signal and a first pressure signal, respectively. The control module confirms that the selected number of pulses occur based on the at least one of the first temperature signal and the first pressure signal.

In other features, a heated manifold surrounds the conduit. The sensor senses the at least one of the first temperature and the first pressure in portions of the conduit heated by the heated manifold. The control module includes a pulse counting module that communicates with the sensor and that counts pulses based on the at least one of the first temperature signal and the first pressure signal. A pulse parameter module selects the number of pulses and the pulse width of the pulses. A comparing module compares the selected number of pulses to the counted number of pulses.

In other features, the control module further comprises a pulse width modulation (PWM) module that generates control signals that are output to the liquid injector. A sensor senses at least one of a second temperature and a second pressure of the liquid from the liquid supply and generates at least one of a second temperature signal and a second pressure signal. The pulse parameter module determines at least one of the number of pulses and the pulse width based on the at least one of the second temperature signal and the second pressure signal.

In other features, the liquid injector includes an automotive-type fuel injector. The liquid injector includes at least one of a pintle style injector, a disc style injector, and a ball seat style injector. The liquid injector and the gas supply are coupled to a fitting that is connected to the conduit. The processing chamber comprises a semiconductor processing chamber.

A system includes the liquid injection system and further includes a lithography patterning tool.

A method for operating a processing chamber comprises receiving a liquid from a liquid supply at a liquid injector; selecting a number of pulses and a pulse width of the liquid injector; selectively pulsing the liquid into a conduit using the liquid injector; supplying gas from a gas supply into the conduit; sensing at least one of a first temperature and a first pressure in the conduit and generating at least one of a first temperature signal and a first pressure signal, respectively; and confirming that the selected number of pulses occur based on the at least one of the first temperature signal and the first pressure signal.

The method further comprises heating the conduit. The method further comprises sensing the at least one of the first temperature and the first pressure in portions of the conduit that are heated. The method further comprises counting pulses based on the at least one of the first temperature signal and the first pressure signal; and comparing the selected number of pulses to the counted number of pulses.

In other features, the method includes generating pulse width modulation control signals that are output to the liquid injector. The method includes sensing at least one of a second temperature and a second pressure of the liquid from the liquid supply and generating at least one of a second temperature signal and a second pressure signal. The method includes determining at least one of the number of pulses and the pulse width based on the at least one of the second temperature signal and the second pressure signal.

In other features, the liquid injector includes an automotive-type fuel injector. The liquid injector includes at least one of a pintle style injector, a disc style injector, and a ball seat style injector. The liquid injector and the supply are coupled to a fitting that is connected to the conduit. The processing chamber comprises a semiconductor processing chamber.

A semiconductor manufacturing method further comprises at least one of before and after placing a substrate in the processing chamber: applying photoresist to the substrate; exposing the photoresist to light; patterning the photoresist and transferring the pattern to the substrate; and selectively removing the photoresist from the substrate.

A non-transitory computer machine-readable medium comprises program instructions for control of a processing chamber. The program instructions comprise code for: selecting a number of pulses and a pulse width of a liquid injector receiving a liquid from a liquid supply; selectively pulsing the liquid into a conduit using the liquid injector; supplying gas into the conduit; sensing at least one of a first temperature and a first pressure in the conduit and generating at least one of a first temperature signal and a first pressure signal, respectively; and confirming that the selected number of pulses occur based on the at least one of the first temperature signal and the first pressure signal.

A liquid injection system for a processing chamber includes a manifold defining a fluid passageway receiving gas from a gas supply. A liquid injector is arranged in the manifold that receives a liquid from a liquid supply and selectively pulses the liquid into the fluid passageway. A control module selects a number of pulses and a pulse width of the liquid injector. A sensor is arranged in the manifold, senses at least one of a first temperature and a first pressure in the fluid passageway and generates at least one of a first temperature signal and a first pressure signal. The control module confirms that the selected number of pulses occur based on the at least one of the first temperature signal and the first pressure signal.

In other features, the manifold is a heated manifold. The control module includes a pulse counting module that communicates with the sensor and that counts pulses based on the at least one of the first temperature signal and the first pressure signal, a pulse parameter module that selects the number of pulses and the pulse width of the pulses, and a comparing module that compares the selected number of pulses to the counted number of pulses.

In other features, the control module further comprises a pulse width modulation (PWM) module that generates control signals that are output to the liquid injector. A sensor senses at least one of a second temperature and a second pressure of the liquid from the liquid supply and generates at least one of a second temperature signal and a second pressure signal.

In other features, the pulse parameter module determines at least one of the number of pulses and the pulse width based on the at least one of the second temperature signal and the second pressure signal. The liquid injector includes an automotive-type fuel injector. The processing chamber comprises a semiconductor processing chamber.

In other features, a nozzle is arranged in the fluid passageway upstream from the injector. The injector is arranged perpendicular to the fluid passageway. The liquid injector includes at least one of a pintle style injector, a disc style injector, and a ball seat style injector.

A semiconductor manufacturing system includes the liquid injection system and further includes a lithography patterning tool.

A method for operating a processing chamber includes arranging a liquid injector in a manifold defining a fluid passageway receiving gas from a gas supply; selecting a number of pulses and a pulse width of the liquid injector; receiving a liquid from a liquid supply at the injector and selectively pulsing the liquid into the fluid passageway; sensing at least one of a first temperature and a first pressure in the fluid passageway and generating at least one of a first temperature signal and a first pressure signal; and confirming that the selected number of pulses occur based on the at least one of the first temperature signal and the first pressure signal.

In other features, the method includes heating the manifold. The method includes counting pulses based on the at least one of the first temperature signal and the first pressure signal; and comparing the selected number of pulses to the counted number of pulses.

In other features, the method includes generating pulse width modulation (PWM) control signals that are output to the liquid injector. The method includes sensing at least one of a second temperature and a second pressure of the liquid from the liquid supply and generating at least one of a second temperature signal and a second pressure signal. The method includes determining at least one of the number of pulses and the pulse width based on the at least one of the second temperature signal and the second pressure signal.

In other features, the liquid injector includes an automotive-type fuel injector. The processing chamber comprises a semiconductor processing chamber. The method includes arranging a nozzle in the fluid passageway upstream from the injector. The method includes arranging the liquid injector perpendicular to the fluid passageway.

In other features, the liquid injector includes at least one of a pintle style injector, a disc style injector, and a ball seat style injector.

A semiconductor manufacturing method include the method and further includes at least one of before and after treating a substrate in the processing chamber: applying photoresist to the substrate; exposing the photoresist to light; patterning the photoresist and transferring the pattern to the substrate; and selectively removing the photoresist from the substrate.

A gas injection system for a processing chamber includes a gas injector that receives gas from a gas supply. A sensor is arranged upstream from the gas injector to sense at least one of a first temperature and a first pressure in a fluid passageway between the gas supply and the gas injector and to generate at least one of a first temperature signal and a first pressure signal. A control module communicates with the gas injector and selects a number of pulses and a pulse width of the gas injector to provide a predetermined flow of the gas to the processing chamber based on the at least one of the first temperature signal and the first pressure signal.

In other features, the control module includes a pulse parameter module that selects the number of pulses and the pulse width of the pulses and a pulse width modulation (PWM) module that generates control signals that are output to the gas injector.

In other features, the gas injector includes an at least one of automotive-type fuel injector. The gas injector includes at least one of a pintle style injector, a disc style injector, and a ball seat style injector. The processing chamber comprises a semiconductor processing chamber. The control module varies the pulse width above a predetermined pulse width to cause pulsing of plasma in the semiconductor processing chamber due to the gas injection.

In other features, the control module varies the pulse width below the predetermined pulse width to prevent pulsing of plasma in the semiconductor processing chamber due to the gas injection.

A semiconductor manufacturing system includes the gas injection system and further includes a lithography patterning tool.

A method for operating a processing chamber includes arranging a sensor upstream from a gas injector that receives gas from a gas supply; sensing at least one of a first temperature and a first pressure in a fluid passageway between the gas supply and the gas injector and generating at least one of a first temperature signal and a first pressure signal; and selecting a number of pulses and a pulse width of the gas injector to provide a predetermined flow of the gas to the processing chamber based on the at least one of the first temperature signal and the first pressure signal.

In other features, the method includes generating control signals that are output to the gas injector. The gas injector includes an automotive-type fuel injector. The gas injector includes at least one of a pintle style injector, a disc style injector, and a ball seat style injector. The processing chamber comprises a semiconductor processing chamber.

In other features, the method includes varying the pulse width above a predetermined pulse width to cause pulsing of plasma in the semiconductor processing chamber due to injection of the gas. The method includes varying the pulse width below the predetermined pulse width to prevent pulsing of plasma in the semiconductor processing chamber due to injection of the gas.

A semiconductor manufacturing method includes the method and further includes at least one of before and after placing a substrate in the processing chamber: applying photoresist to the substrate; exposing the photoresist to light; patterning the photoresist and transferring the pattern to the substrate; and selectively removing the photoresist from the substrate.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF DRAWINGS

The present disclosure will become more fully understood from the detailed description and the accompanying drawings, wherein:

FIG. 1 is a functional block diagram of an example of a liquid injection system for a processing chamber according to the present disclosure;

FIG. 2 is a graph illustrating temperature and pressure monitoring of delivery of the liquid precursor into a heated manifold according to the present disclosure;

FIG. 3 is a flowchart illustrating an example method for operating the injector of FIG. 1 according to the present disclosure;

FIG. 4 is a flowchart illustrating the use of the liquid injection system for depositing a film according to the present disclosure;

FIGS. 5A and 5B illustrate a gas and liquid injection system for a multi-chamber system;

FIG. 6 is a functional block diagram of another liquid injection system for a processing chamber according to the present disclosure;

FIG. 7 is a cutaway view of an example of an automotive-type fuel injector;

FIGS. 8A and 8B are functional block diagrams of a gas injection system for a processing chamber according to the present disclosure;

FIG. 9 illustrates mass flow rate as a function of upstream pressure using the gas injection system of FIG. 8;

FIGS. 10A-10C show the results of different pulse periods on the impedance of the plasma in the processing chamber with the injector located in the gas box;

FIGS. 11A and 11B show the results of the same pulse period when the injector is located near the gas box as compared to near the shower head;

FIGS. 12A-12C show the results of different pulse widths or duty cycles;

FIG. 13 is a flowchart of an example method for using gas injection to supply gas to a processing chamber; and

FIG. 14 is a functional block diagram of a semiconductor manufacturing system including a lithography patterning tool.

### DESCRIPTION

The following description is merely illustrative in nature and is in no way intended to limit the disclosure, its application, or uses. For purposes of clarity, the same reference numbers will be used in the drawings to identify similar elements. As used herein, the phrase at least one of A, B, and C should be construed to mean a logical (A or B or C), using a non-exclusive logical OR. It should be understood that steps within a method may be executed in different order without altering the principles of the present disclosure.

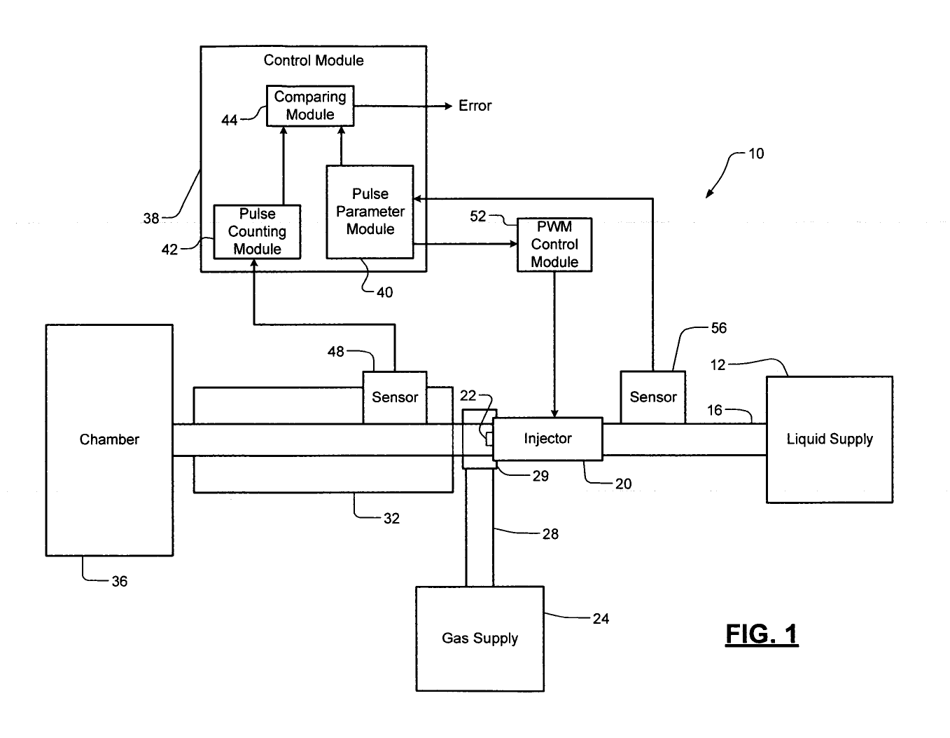

FIGS. 1-7 of the present disclosure relate to various liquid injection systems for precise delivery of liquid and/or gas to a process. The liquid injection systems include automotive-style fuel injectors and a control system to ensure that the desired amount of liquid or gas is delivered to the process. The automotive-style fuel injectors may be modified with different materials, flowrates or other operating parameters to suit the needs of a particular process. In some examples, the liquid that is injected is vaporized by a heated manifold to produce gas. The liquid injection systems allow injection of liquid and/or gas to be made closer to the process, which reduces time delay when changes are made. The liquid injection systems also tend to reduce waste.

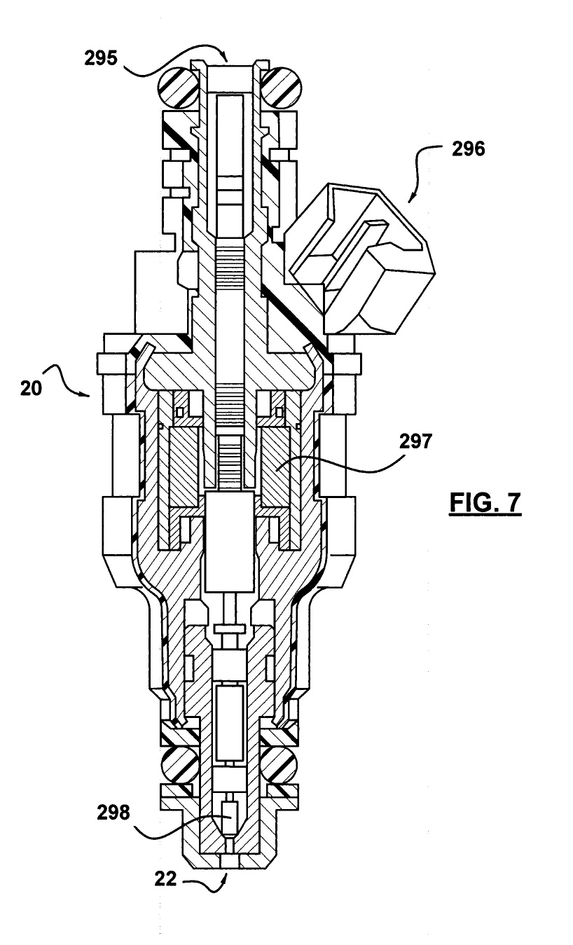

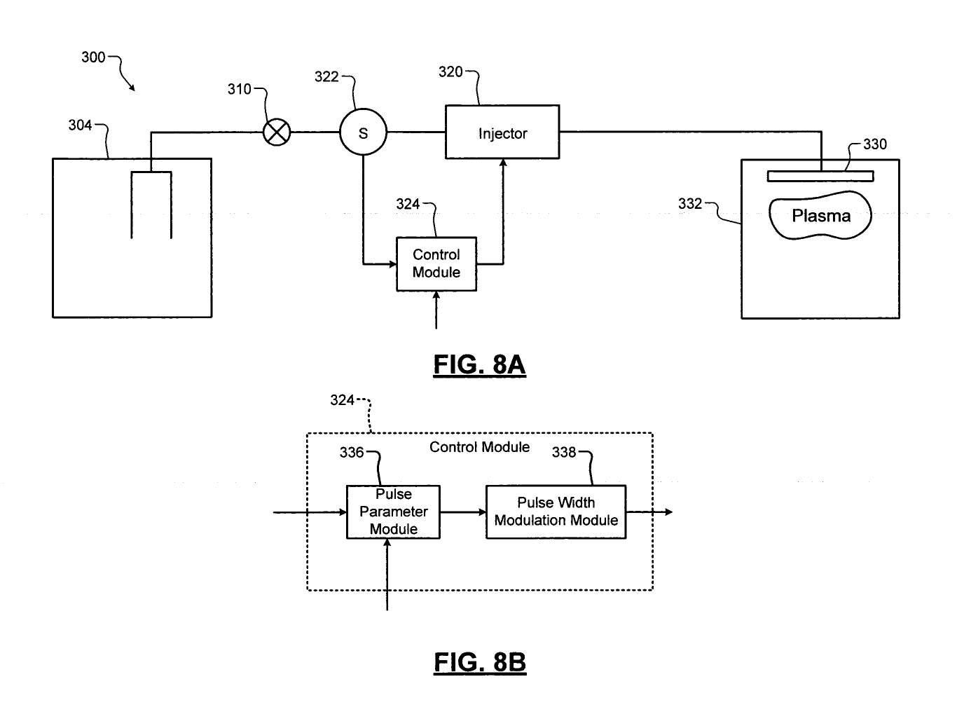

In addition, FIGS. 8-13 of the present disclosure relate to gas injection systems for precise delivery of gas to a process. The gas injection systems also include automotive-style fuel injectors and a control system to ensure that the desired amount of gas is delivered to the process. The automotive-style fuel injectors may be modified with different materials, flowrates or other operating parameters to suit the needs of a particular process. According to the present disclosure, the control system monitors temperature and/or pressure upstream from the injector to control a downstream pressure, flow rate or concentration of the gas supplied to the process. Downstream temperature and/or pressure may also be monitored.

Referring now to FIG. 1, an example of a liquid injection system 10 for a chamber according to the present disclosure is shown. The liquid injection system 10 supplies liquid from a liquid supply 12 through a conduit 16 to an injector 20 having an injector tip 22.

A gas supply 24 supplies gas through a conduit 28, which is connected to a fitting 29. The gas may be heated or unheated. The injector tip 22 may be disposed inside the fitting 29 such that gas flows across the injector tip 22 as it flows to the processing chamber.

A heated manifold 32 receives flow of gas and the precursor from the fitting 29. The injector 20 injects relatively small droplets of the precursor into the heated manifold 32. The droplets are sheared by the gas and heated by the heated manifold 32 to a gaseous state. The precursor gas is delivered to a chamber 36. As can be appreciated, it is important to prevent liquid droplets of the precursor from reaching the processing chamber 36 and contaminating the substrate.

A sensor 48 such as a temperature sensor or a pressure sensor senses either the temperature or pressure of the precursor gas. The sensor 48 generates a temperature signal or a pressure signal, which is output to a control module 38. The control module 38 monitors the temperature signal and/or the pressure signal to ensure that a selected number N of pulses occur, where N is an integer greater than 0. As discussed above, it is important when depositing films such as conformal films or in other processes to have the correct amount of precursor or other liquid (or gas) without excess to minimize cost.

The control module 38 may include a pulse parameter module 40 that outputs a duty cycle, a pulse width, and a number of pulses N to a pulse width modulation (PWM) control module 52. The PWM control module 52 outputs switch signals to the injector 20. A relay may be used between the PWM control module 52 and the injector 20.

The control module 38 includes a pulse counting module 42 that determines the number of pulses that actually occurred. The control module 38 includes a comparing module 44 that compares the desired number of pulses N to the number of pulses that actually occurred. The comparing module 44 may generate an error signal when a mismatch occurs.

One or more additional sensors 56, such as a temperature sensor and/or a pressure sensor, monitor conditions such as temperature and/or pressure on an inlet side of the injector 20. The pulse parameter module 40 may adjust one or more of the pulse parameters such as the duty cycle, the pulse width, and the number of pulses N in response to changes in the sensed conditions at the inlet side of the injector 20. For example only, changes can be made by the pulse parameter module 40 to the pulse parameters in response to changes in the temperature and/or pressure conditions. Changes can be made continuously, on a discrete time basis, on an event basis or using other criteria.

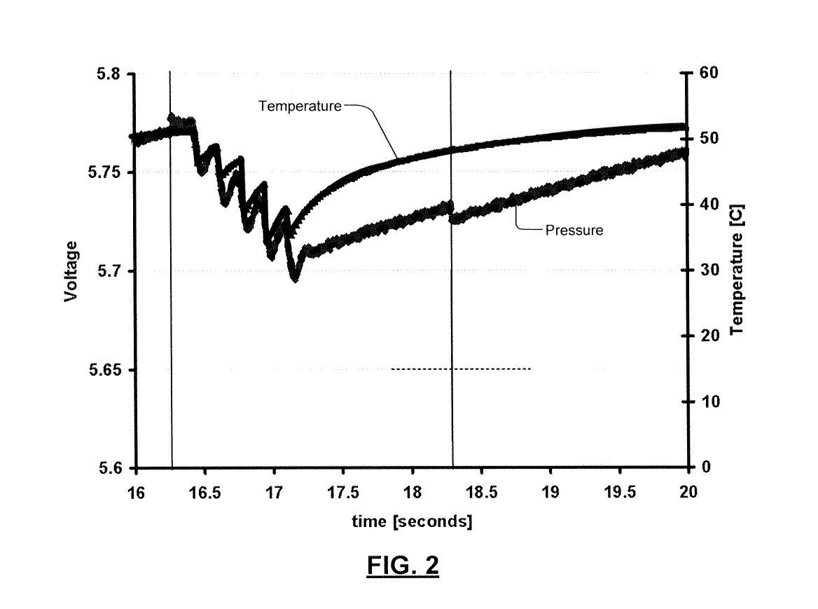

Referring now to FIG. 2, a graph of temperature and pressure values are shown during injection of the liquid precursor into the heated manifold 32. As described above, in some applications it is important to deliver a predetermined amount of liquid without waste. Therefore, it is important to determine whether all of the N pulses have occurred. The pulses may not occur in the event that the injector is clogged and/or an electrical problem occurs in the control system.

As the injector injects liquid into the heated manifold, the temperature and pressure of the gas in the heated manifold 32 varies. More particularly, the pressure increases in response to an injection pulse and then falls. Likewise, the temperature in the heated manifold decreases and then rises. While the sensor may measure either the pressure or the temperature, suitable temperature sensors tend to have a lower cost.

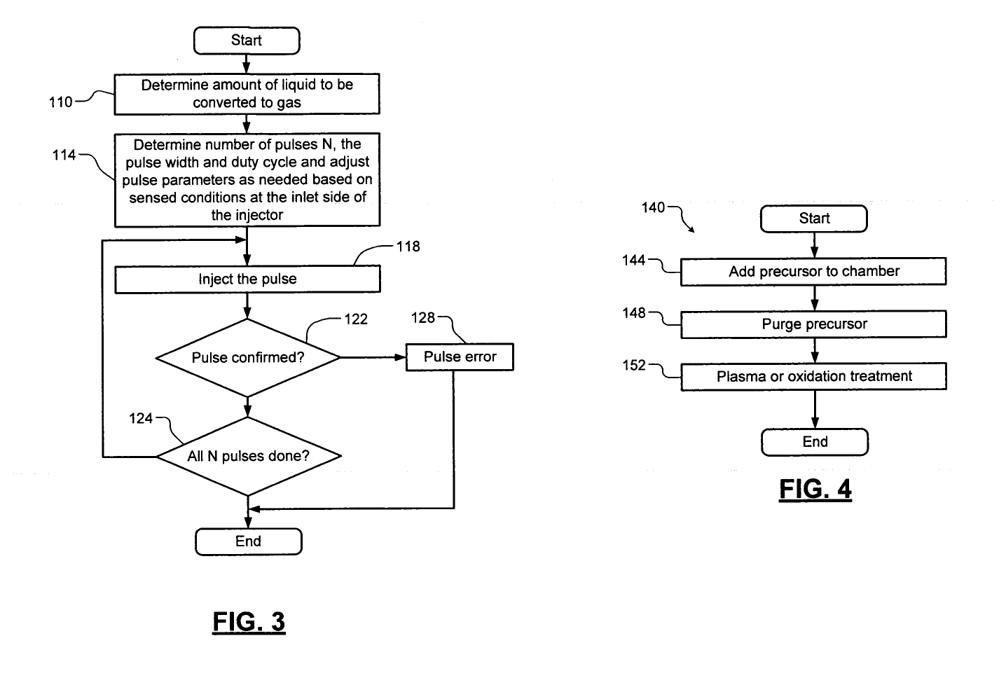

Referring now to FIG. 3, an example method 100 for operating the injector 20 of FIG. 1 is shown. At 110, the amount of liquid (such as a precursor) to create a desired amount of gas is determined. The conversion of the desired amount of liquid to gas can be a calculation that is modified based on feedback from an upstream sensor. The calculation can be performed by the pulse parameter module or the PWM module. The amount of liquid can be set by an operator. At 114, the number of pulses N, the pulse width for each of the pulses and the duty cycle are determined. If there are changes to sensed conditions on the inlet side of the injector 20 as measured by the sensor 56, control determines whether or not to change one or more of the pulse parameters. At 118, one of the N pulses is injected. At 122, control determines whether the pulse occurred. If the pulse occurred, control determines whether all of the N pulses have been injected. If 124 is false, control continues with 118. If control fails to confirm that one of the pulses occurred, an error is generated at 128. Otherwise when all of the N pulses have been injected, control ends. While pulse by pulse confirmation is shown in FIG. 3, all of the pulses may be injected independently of the timing of confirmation that all of the pulses occurred. Still other variations are contemplated.

Referring now to FIG. 4, the liquid injection system can be used to supply precursor gas for depositing a film such as a conformal film. As can be appreciated, the liquid injector system can be used in other systems. For example only, the liquid injector system can be used to deposit other types of film and/or to deliver gas or liquid to other types of processes, etc. An example of part of a method 140 for depositing a conformal film is shown. Gaseous precursor is generated by injecting liquid precursor as described above. The gaseous precursor is then delivered to a processing chamber at 144. After a predetermined period, the precursor gas is purged at 148. After another predetermined period, plasma or oxidation treatment occurs at 152. Blocks 144, 148 and 152 may be repeated to build up the thickness of the conformal film.

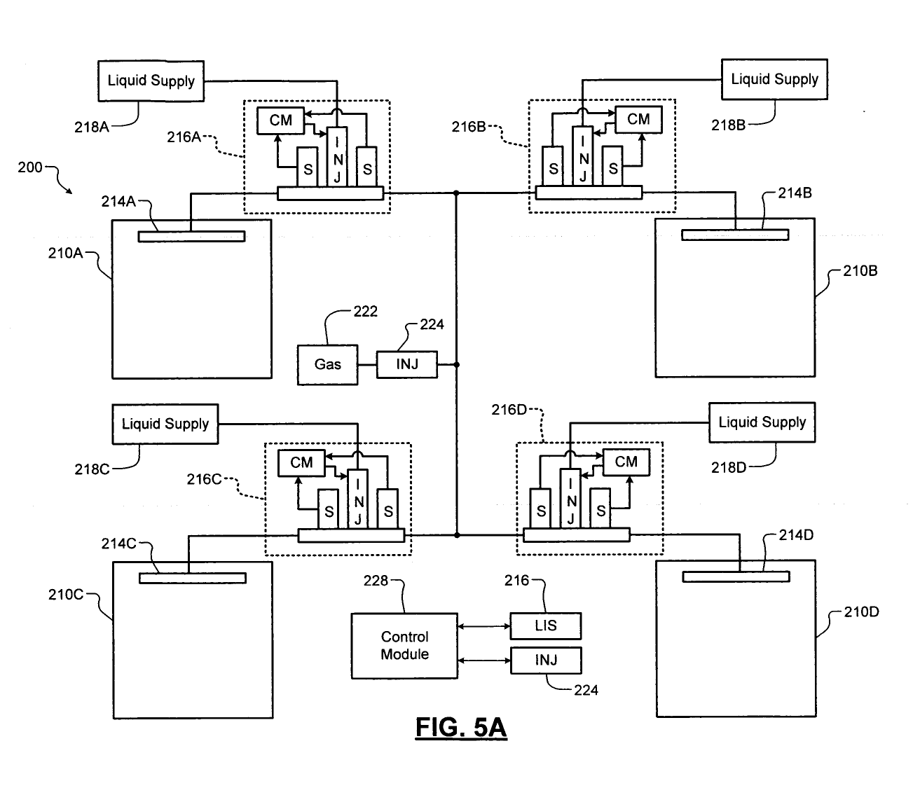

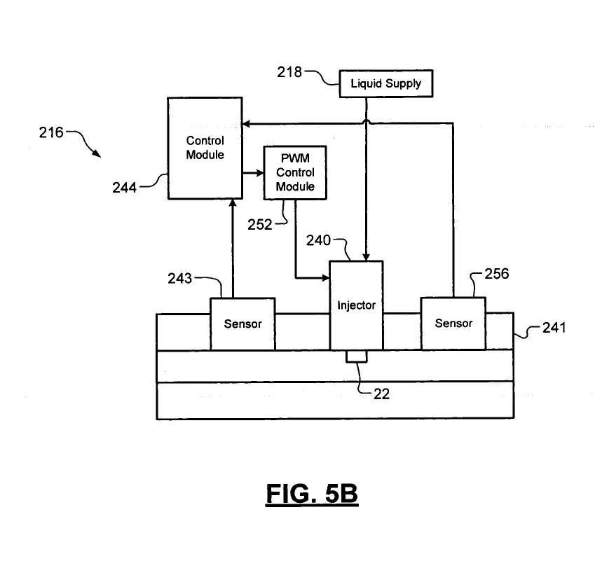

Referring now to FIGS. 5A and 5B, a liquid injection system for a system with multiple chambers or multiple stations of the same chamber is shown. In FIG. 5A, each of the processing chambers 210A, 210B, 210C and 210D includes a shower head 214A, 214B, 214C and 214D, respectively. Each of the processing chambers 210A, 210B, 210C and 210D delivers liquid 218A, 218B, 218C and 218D from a supply to a liquid injection system (LIS) 216A, 216B, 216C and 216D (collectively, LIS 216).

In FIG. 5B, each of the LIS 216 includes a liquid injector 240 connected to a heated manifold 241. A sensor 243 monitors temperature or pressure. A control module (CM) 244 monitors the temperature or pressure to confirm that the pulses have in fact occurred. The control module 244 sends control signals to a PWM control module 252, which outputs control signals to the injector 240. An additional sensor 256, such as temperature and/or pressure sensor, monitors conditions on an inlet side of the injector 240, in a similar manner described above with respect to sensor 56.

In FIGS. 5A and 5B, conduits supply gas to inlets of the heated manifolds 241. The gas may also be supplied by a gas supply 222 via an injector 224. Another system control module 228 may be in communication with the LIS 216 and with the gas injector 224 to control the process.

Referring now to FIG. 6, another liquid injection system 290 for a processing chamber according to the present disclosure is shown. In this example, the injector 20 is mounted on the heated manifold 32. The injector 20 may be arranged perpendicular to a direction of gas flowing through the heated manifold 32, although other orientations may be used. Gas is supplied by a gas supply 24 through a conduit 28 to a nozzle 294, which increases a velocity of the gas. For example only, the nozzle 294 can be a convergent divergent (CD) nozzle. The nozzle 294 may increase a velocity of the gas to a high velocity, a sonic velocity or a supersonic velocity. The nozzle increases shear of the droplets by increasing the velocity of the gas flow in the tube/conduit. In one example, a droplet size of less than 10 microns at a flow of ˜10 slm through a sonic nozzle was used.

As can be appreciated, the injector 20 may be arranged at varying angles relative to the direction of gas flowing through the heated manifold 32. For example, the conduit 28 and the injector 20 may form an angle of approximately 120° relative to each other and to the direction of gas flowing through the heated manifold 32, although other angles may be used.

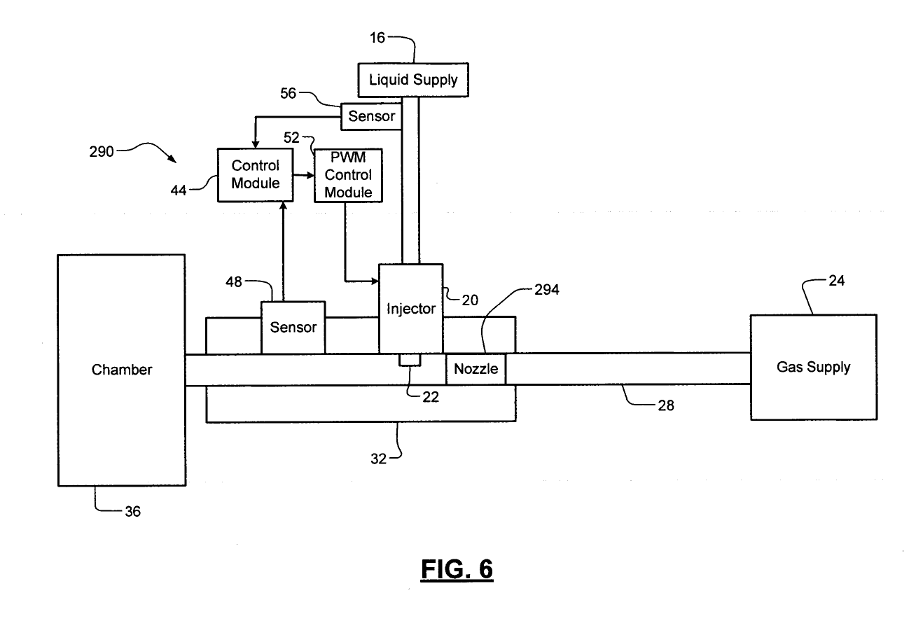

Referring now to FIG. 7, an example of an automotive-type fuel injector is shown. As can be appreciated, while a pintle style injector is shown other designs of automotive-style fuel injectors can be used. For example only, disc style injectors, ball seat style injectors and/or other types of injectors may be used. The injector 20 includes an inlet end 205. The open and closed position of the injector 20 may be controlled electrically via a control terminal 296, which allows a coil 297 to be energized and de-energized. When the coil 297 is energized, a plunger 298 of the injector 20 moves and liquid is injected from the injector tip 22.

While the examples in FIGS. 1-7 supply liquid that is vaporized and supplied to a processing chamber in a semiconductor processing system, the liquid injection systems can be used to supply liquid and/or gas to other types of systems or processes.

Referring now to FIGS. 8A and 8B, a gas injection system 300 according to the present disclosure is shown. While the examples in FIG. 8A-12C supply gas to a processing chamber in a film processing system, the gas injection systems can be used to supply gas to other types of systems or processes. The gas injection system 300 supplies gas via conduits and a check valve 310 from a gas box 304 to an injector 320. A sensor 322 monitors the pressure of the gas on an upstream side of the injector 320 and generates a pressure signal. The sensor 322 may also be used to monitor a temperature of gas supplied to the upstream side of the injector. A control module 324 receives the pressure signal from the pressure sensor 322 and generates a control signal to control pulsing of the injector 320. For example, the control module 324 may output a signal to a relay, such as a solid-state relay, which controls the injector 320. An output of the injector 320 supplies gas at a predetermined mass flow rate to a shower head 330 of a chamber 332. Downstream temperature and/or pressure may also be monitored. In FIG. 8B, an example of the control module 324 is shown. The control module in FIG. 8B includes a pulse parameter module 336 that determines a pulse width and number of pulses sufficient to provide a desired gas concentration. A pulse width modulation (PWM) module 338 generates control signals for the injector 320 based on control signals from the pulse parameter module 336.

Referring now to FIG. 9, mass flow rate is shown as a function of upstream pressure using the gas injection system of FIG. 8. As can be appreciated, the mass flow rate is a relatively linear function of the upstream pressure for various gases such as argon (Ar), helium (He) and nitrogen (N₂). The mass flow rate is given by:

$$\dot{m} = CAP \sqrt{( \frac{kM}{ZRT} ) {( \frac{2}{k + 1} )}^{( k + 1 ) / ( k - 1 )}}$$

Where m is the mass flow rate in kg/s, C is the discharge coefficient, A is the discharge hole cross-sectional area in m², k is equal to cₚ/cᵥ, cₚ is the specific heat of the gas at constant pressure, cᵥ is the specific heat of the gas at constant volume, p is the real gas density at P and T in kg/m², P is the absolute upstream pressure of the gas in Pa, and M is the gas molecular mass in kg/mole.

Since there is linear dependence on pressure, flow through the injector 320 appears to be choked. Therefore, the compressible gas flow theory is applicable. Flow is independent of the downstream pressure as long as the choking condition is met. As a result, the downstream flow can be maintained by controlling the upstream pressure. The accuracy of the flow is dependent upon the accuracy of the pressure sensor 322. Pressure sensors have an accuracy of ˜1% of reading/0.25% full scale, which is similar to the accuracy of more expensive mass flow controllers.

As can be appreciated, the injector 320 can be located in various positions between the gas box 304 and the shower head 330 or chamber 332. Referring now to FIGS. 9A-9C, a measured impedance of the plasma inside the processing chamber 332 is shown for different pulse periods with the injector 320 located in or near the gas box 304. The examples in FIGS. 9A-9C were generated with a chamber pressure of 2 Torr and 500 Watt (W) plasma. The impedance inside the processing chamber 332 was measured with a voltage and current probe arranged in the processing chamber 332. The gas flow rate through the gas injector 320 was approximately 10 standard liters per minute (slm) of N₂. A duty cycle of the gas injector 320 was set to 50%.

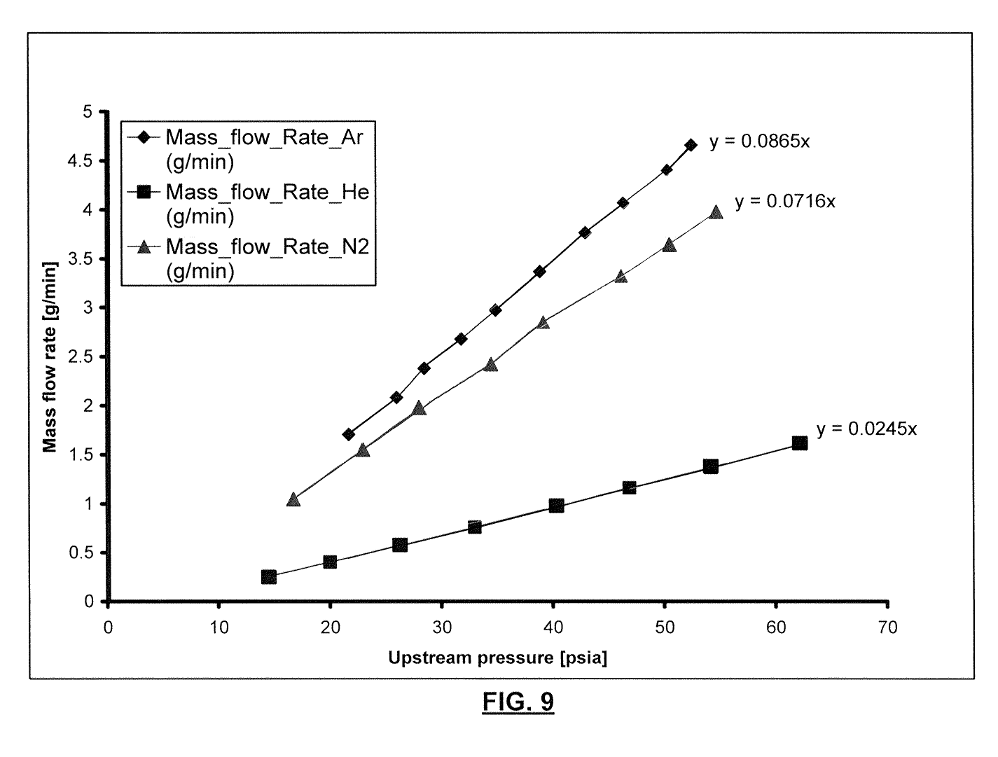

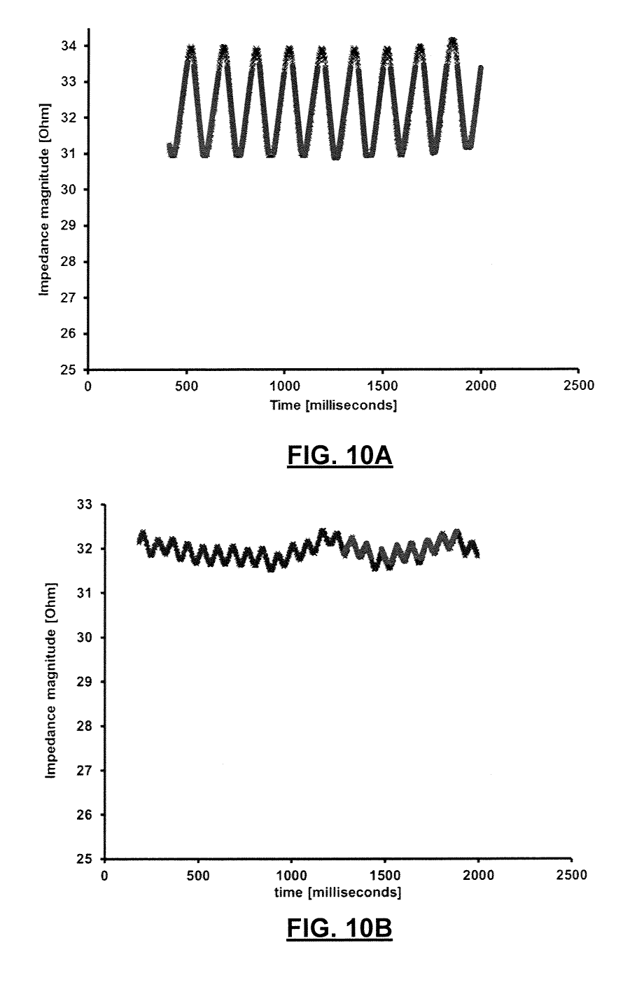

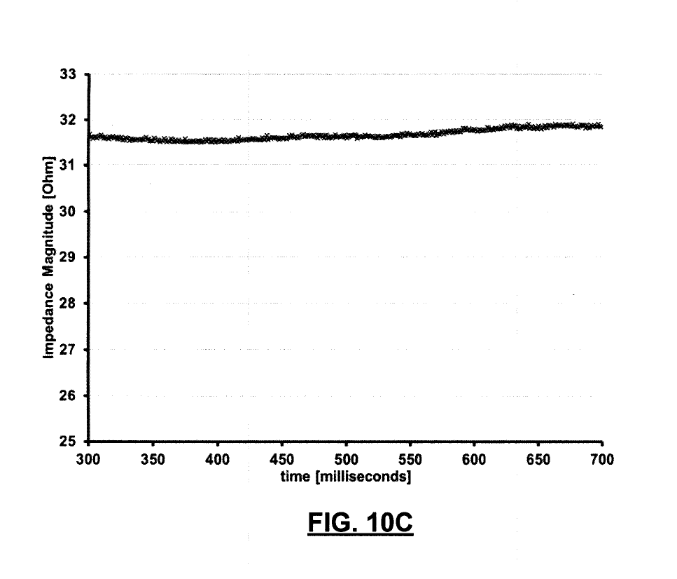

In FIGS. 10A and 10B, pulsing of the impedance in the processing chamber 332 occurs for pulses with a period of 166 ms and 80 ms, respectively. However, in FIG. 10C, pulsing of the impedance does not occur for pulses with a period of 40 ms. Thus, pulsing does not occur below a predetermined pulse width. When pulsing does occur, the pulsing of the impedance of the plasma matches the pulsing of the injector 320. For the same flow rate, longer injection periods tend to have more plasma pulsing.

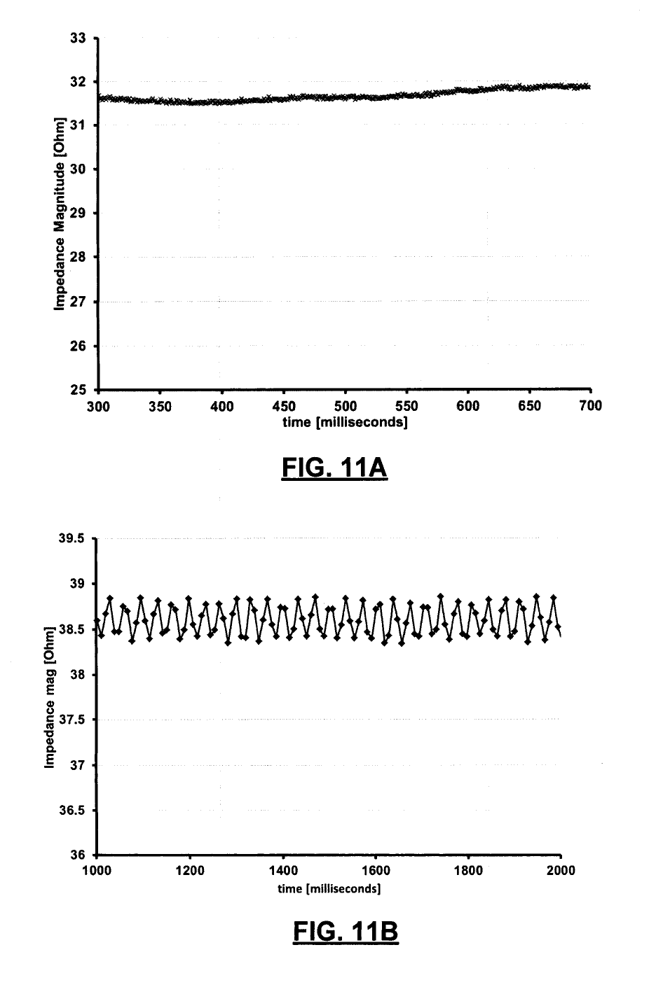

Referring now to FIGS. 11A and 11B, results are shown for the same pulse period with the injector 320 located in different positions. In FIG. 11A, the injector 320 is located near the gas box 304. In FIG. 11B, the injector 320 is located near the shower head. Approximately 3 slm flow of clean dry air (CDA) is used. Both FIGS. 11A and 11B show a 40 ms pulse period. When the injector 320 is located near the shower head, pulsing of the injector 320 affects the impedance of the plasma. However, the pulsing of the injector is not apparent in the impedance of the plasma when the injector 320 is located adjacent to the gas box 304. As can be appreciated, the travel time from the point of injection to the plasma tends to have an impact on whether pulsing of the injector impacts the impedance of the plasma.

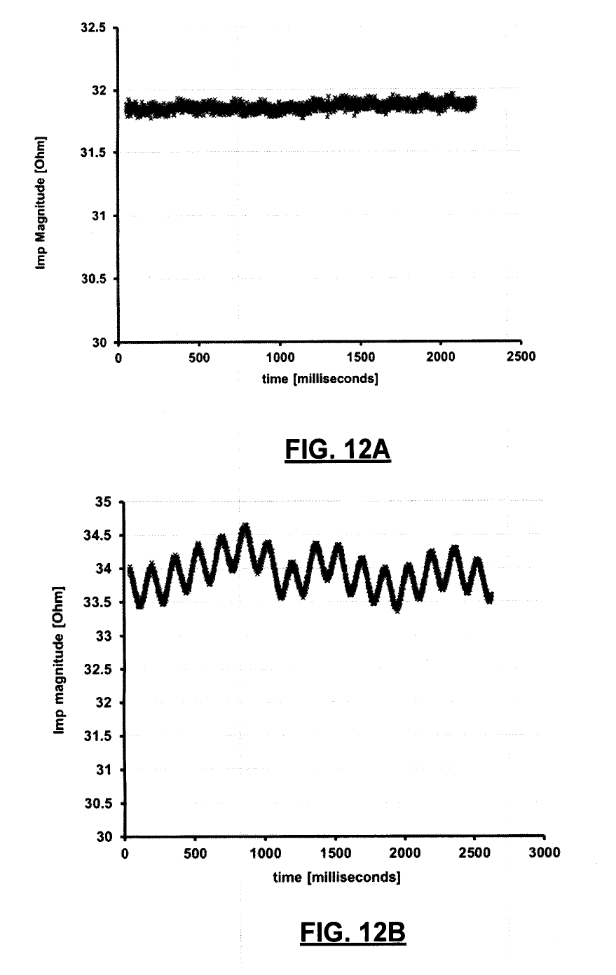

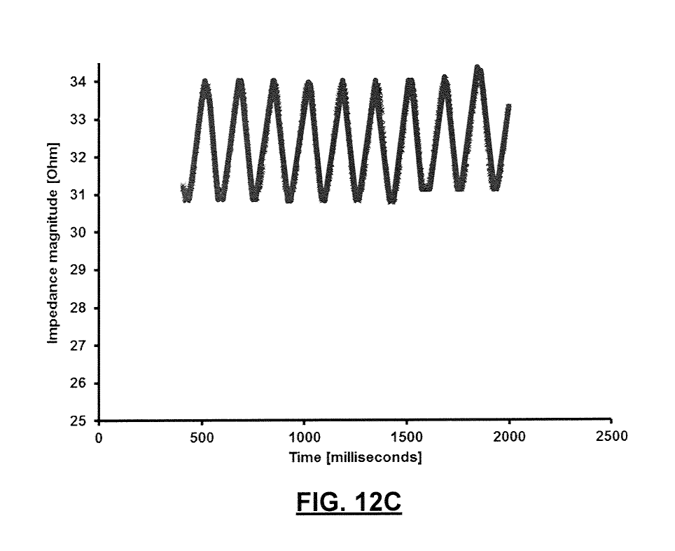

Referring now to FIGS. 12A-12C, the injector 320 is located adjacent to the shower head. In this example, a period of 160 ms is used and chamber pressure is set to 2 Torr. FIG. 12A shows an 8 ms pulse followed by 152 ms without a pulse. FIG. 12B shows a 32 ms pulse followed by 128 ms without a pulse. FIG. 12C shows an 80 ms pulse followed by 80 ms without a pulse. Larger pulse widths tend to have more effect on the impedance of the plasma. Higher flow rates with the same period also tend to have a more significant effect on the impedance of the plasma.

The present disclosure enables different plasma conditions with the same overall flow rate by modifying either PWM parameters and/or injector location. The present disclosure allows differentiated use of the injector where a parameter other than flow rate can be controlled. The present disclosure also allows different deposition conditions with same flow rate. The present disclosure offers a less expensive way to achieve the same effects as more expensive techniques such as plasma pulsers by pulsing the RF or in general excitation energy for the plasma.

For example only, the injectors used in both the liquid and gas injection systems may include automotive-style fuel injectors or automotive style fuel injectors that have been modified for semiconductor applications. Many automotive-style fuel injectors include brass or copper components. In some examples, the brass or copper components may be replaced with components made of steel, aluminum or another metal or alloy that does not contain copper. Still other material changes may be made. Likewise, flow rates of the automotive-style injectors may also be altered to suit a particular semiconductor application.

The apparatus/process described herein may be used in a process for depositing a film on a substrate, etching a film on a substrate, cleaning a film on substrate, chemically treating a film on a substrate, and/or otherwise processing a film on a substrate.

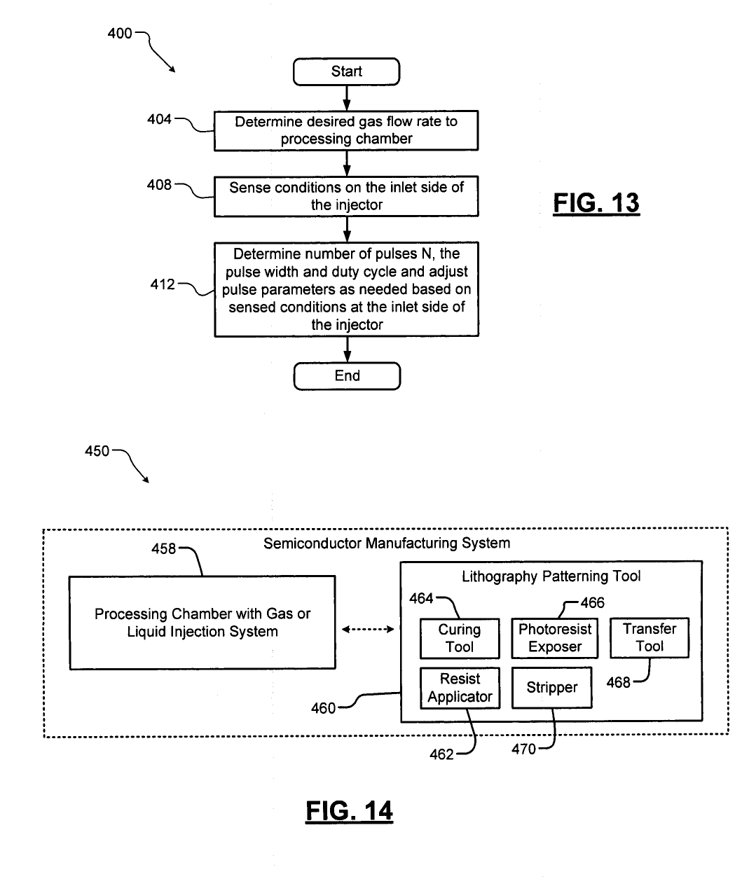

Referring now to FIG. 13, a method for operating the gas injector for a processing chamber is shown at 400. At 404, a desired gas flow rate to the processing chamber is determined. At 408, the conditions such as temperature and pressure at the inlet side of the gas injector are sensed. At 412, the number of pulses N, the pulse width and the duty cycle are determined and adjusted based on the sensed conditions at the inlet side of the gas injector.

Referring now to FIG. 14, a semiconductor manufacturing system 450 includes a processing chamber including a gas or liquid injection system 458 as described above and a lithography patterning tool 460.

The apparatus/process described herein may be used in conjunction with the lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically comprises some or all of the following, each enabled with a number of possible tools: (1) application of photoresist on a workpiece, i.e., substrate, using a resist applicator tool 462 such as a spin-on or spray-on tool; (2) curing of photoresist using a curing tool 464 such as a hot plate or furnace or UV curing tool; (3) exposing the photoresist to visible or UV or x-ray light with a photoresist exposing tool 466 such as a wafer stepper; (4) developing the resist so as to selectively remove resist and thereby pattern it using a tool such as a wet bench; (5) transferring the resist pattern into an underlying film or workpiece by using a transfer tool 468 such as a dry or plasma-assisted etching tool; and (6) removing the resist using a stripping tool 470 such as an RF or microwave plasma resist stripper.

As used herein, the term module may refer to, be part of, or include an Application Specific Integrated Circuit (ASIC); an electronic circuit; a combinational logic circuit; a field programmable gate array (FPGA); a processor (shared, dedicated, or group) that interfaces with memory and executes code; other suitable components that provide the described functionality; or a combination of some or all of the above. The term code, as used above, may include software, firmware, and/or microcode, and may refer to programs, routines, functions, classes, and/or objects. The term shared, as used above, means that some or all code from multiple modules may be executed using a single (shared) processor. In addition, some or all code from multiple modules may be stored by a single (shared) memory. The term group, as used above, means that some or all code from a single module may be executed using a group of processors. In addition, some or all code from a single module may be stored using a group of memories.

The apparatuses and methods described herein may be implemented by one or more computer programs executed by one or more processors. The computer programs include processor-executable instructions that are stored on a non-transitory tangible computer readable medium. The computer programs may also include stored data. Non-limiting examples of the non-transitory tangible computer readable medium are nonvolatile memory, magnetic storage, and optical storage.

The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

What is claimed is:

1. A liquid injection system for a processing chamber, comprising:
a liquid injector that receives a liquid from a liquid supply and that selectively pulses the liquid into a conduit;
a control module that selects a number of pulses and a pulse width of the liquid injector;
a gas supply that supplies gas into the conduit; and
a sensor that senses at least one of a first temperature and a first pressure in the conduit and that generates at least one of a first temperature signal and a first pressure signal, respectively,
wherein the control module confirms that the selected number of pulses occur based on the at least one of the first temperature signal and the first pressure signal.

2. The liquid injection system of claim 1, further comprising a heated manifold surrounding the conduit.

3. The liquid injection system of claim 2, wherein the sensor senses the at least one of the first temperature and the first pressure in portions of the conduit heated by the heated manifold.

4. The liquid injection system of claim 1, wherein the control module includes:
a pulse counting module that communicates with the sensor and that counts pulses based on the at least one of the first temperature signal and the first pressure signal;
a pulse parameter module that selects the number of pulses and the pulse width of the pulses; and
a comparing module that compares the selected number of pulses to the counted number of pulses.

5. The liquid injection system of claim 4, wherein the control module further comprises a pulse width modulation (PWM) module that generates control signals that are output to the liquid injector.

6. The liquid injection system of claim 4, further comprising a sensor that senses at least one of a second temperature and a second pressure of the liquid from the liquid supply and that generates at least one of a second temperature signal and a second pressure signal.

7. The liquid injection system of claim 6, wherein the pulse parameter module determines at least one of the number of pulses and the pulse width based on the at least one of the second temperature signal and the second pressure signal.

8. The liquid injection system of claim 1, wherein the liquid injector includes an automotive-type fuel injector.

9. The liquid injection system of claim 1, wherein the liquid injector includes at least one of a pintle style injector, a disc style injector, and a ball seat style injector.

10. The liquid injection system of claim 1, wherein the liquid injector and the gas supply are coupled to a fitting that is connected to the conduit.

11. The liquid injection system of claim 1, wherein the processing chamber comprises a semiconductor processing chamber.

12. A system comprising the liquid injection system of claim 1 and further comprising a lithography patterning tool.

13. A method for operating a processing chamber, comprising:
receiving a liquid from a liquid supply at a liquid injector;
selecting a number of pulses and a pulse width of the liquid injector;
selectively pulsing the liquid into a conduit using the liquid injector;
supplying gas from a gas supply into the conduit;
sensing at least one of a first temperature and a first pressure in the conduit and generating at least one of a first temperature signal and a first pressure signal, respectively; and
confirming that the selected number of pulses occur based on the at least one of the first temperature signal and the first pressure signal.

14. The method of claim 13, further comprising heating the conduit.

15. The method of claim 14, further comprising sensing the at least one of the first temperature and the first pressure in portions of the conduit that are heated.

16. The method of claim 13, further comprising:
counting pulses based on the at least one of the first temperature signal and the first pressure signal; and
comparing the selected number of pulses to the counted number of pulses.

17. The method of claim 16, further comprising generating pulse width modulation control signals that are output to the liquid injector.

18. The method of claim 16, further comprising sensing at least one of a second temperature and a second pressure of the liquid from the liquid supply and generating at least one of a second temperature signal and a second pressure signal.

19. The method of claim 18, further comprising determining at least one of the number of pulses and the pulse width based on the at least one of the second temperature signal and the second pressure signal.

20. The method of claim 13, wherein the liquid injector includes an automotive-type fuel injector.

21. The method of claim 13, wherein the liquid injector includes at least one of a pintle style injector, a disc style injector, and a ball seat style injector.

22. The method of claim 13, wherein the liquid injector and the supply are coupled to a fitting that is connected to the conduit.

23. The method of claim 13, wherein the processing chamber comprises a semiconductor processing chamber.

24. A semiconductor manufacturing method comprising the method of claim 13 and further comprising:
at least one of before and after treating a substrate in the processing chamber:
applying photoresist to the substrate;
exposing the photoresist to light;
patterning the photoresist and transferring the pattern to the substrate; and
selectively removing the photoresist from the substrate.

25. A non-transitory computer machine-readable medium comprising program instructions for control of a processing chamber, the program instructions comprising:
code for:
selecting a number of pulses and a pulse width of a liquid injector receiving a liquid from a liquid supply;
selectively pulsing the liquid into a conduit using the liquid injector;
supplying gas into the conduit;
sensing at least one of a first temperature and a first pressure in the conduit and generating at least one of a first temperature signal and a first pressure signal, respectively; and
confirming that the selected number of pulses occur based on the at least one of the first temperature signal and the first pressure signal.
